(19) United States
(12) Patent Application Publication
(10) Pub. No.: US 2013/0164937 A1
(43) Pub. Date: Jun. 27, 2013

(54) CHEMICAL MECHANICAL PLANARIZATION SITE ISOLATION REACTOR

(71) Applicant: Glen Egami, San Jose, CA (US)

(72) Inventor: Glen Egami, San Jose, CA (US)

(73) Assignee: Intermolecular, Inc., San Jose, CA (US)

(21) Appl. No.: 13/333,686

(22) Filed: Dec. 21, 2011

(51) Int. Cl. H01L 21/306; H01L 21/304

(52) U.S. Cl. 438/693; 156/345.12; 257/E21.23

(57) ABSTRACT

The embodiments describe systems and methods for combinatorial processing of a substrate. In some embodiments, chemical mechanical polishing (CMP) techniques are combinatorially processed and evaluated. The CMP system is capable of providing a localized planarization surface to at least a region of a substrate being combinatorially processed. In some embodiments, the CMP system comprises a reactor assembly having plurality of reaction chambers, with at least a reaction chamber comprising a rotatable polishing head, slurry and chemical distribution, chemical and water rinse, and slurry and fluid removal. Accordingly, from a single substrate, a variety of materials, process conditions, and process sequences may be evaluated for desired planarization results.

### FIELD OF THE INVENTION

The present invention relates generally to combinatorial methods for device process development.

### BACKGROUND OF THE INVENTION

The manufacture of advanced semiconductor devices entails the integration and sequencing of many unit processing steps, with potential new material and process developments. The precise sequencing and integration of the unit processing steps enables the formation of functional devices meeting desired performance metrics such as power efficiency, signal propagation, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been used in wet chemical processing such as etching and cleaning. HPC processing techniques have also been used in deposition processes such as physical vapor deposition (PVD), atomic layer deposition (ALD), and chemical vapor deposition (CVD). However, currently there are no systems for chemical mechanical polishing (CMP) multiple site isolated regions on a substrate. Therefore there is a need for combinatorially chemical mechanical polishing isolated surface regions on a substrate.

### SUMMARY OF THE DESCRIPTION

In some embodiments, the invention discloses chemical mechanical polishing (CMP) an isolated region of a substrate. In some embodiments, a flow cell comprises a rotatable polishing head for planarizing the portion of the substrate defined by the chamber wall of the flow cell. The flow cell can further comprise inlet conduits for introducing slurry, chemical and water rinse, and outlet conduits for removing materials, such as slurry waste or rinse liquid waste, from the isolated surface region.

In some embodiments, the invention discloses methods for CMP an isolated region of a substrate, comprising wetting the isolated region before disposing a polishing head, polishing the isolated region while flowing slurry on another area of the isolated region, and rinsing the isolated region after completed planarizing.

In some embodiments, the present invention discloses systems and methods for combinatorially chemical mechanical polishing (CMP) and evaluating multiple isolated regions on a substrate. The CMP process is capable of providing localized planarization surfaces to multiple isolated regions in a combinatorial manner. Accordingly, from a single substrate, a variety of materials, process conditions, and process sequences may be evaluated for desired planarization results.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing in accordance with one embodiment of the invention.

FIG. 3 illustrates a schematic diagram of a substrate that has been processed in a combinatorial manner.

FIG. 4 illustrates a schematic diagram of a combinatorial wet processing system according to an embodiment described herein.

FIG. 5 illustrates an exemplary CMP reactor according to some embodiments of the present invention.

FIGS. 6-7 illustrate an exemplary planetary rotating polishing head according to some embodiments of the present invention.

FIGS. 8A-8D illustrate an exemplary method for polishing a site isolated region according to some embodiments of the present invention.

FIG. 9 illustrates a non-contact exemplary CMP reactor according to some embodiments of the present invention.

FIG. 10 illustrates an exemplary slurry and chemical distribution according to some embodiments of the present invention.

FIG. 11 illustrates an exemplary flowchart for polishing site isolated regions according to some embodiments of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The present invention relates to systems and methods for isolating a surface region of a substrate, without contacting the surface, during a wet processing of the remaining surface. The present non-contact isolation can reduce or eliminate particulates or debris, especially at the boundary of the protected region. In some embodiments, the present invention discloses methods and systems for use in high productivity combinatorial processes.

“Combinatorial Processing” generally refers to techniques of differentially processing multiple regions of one or more substrates. Combinatorial processing generally varies materials, unit processes or process sequences across multiple regions on a substrate. The varied materials, unit processes, or process sequences can be evaluated (e.g., characterized) to determine whether further evaluation of certain process sequences is warranted or whether a particular solution is suitable for production or high volume manufacturing.

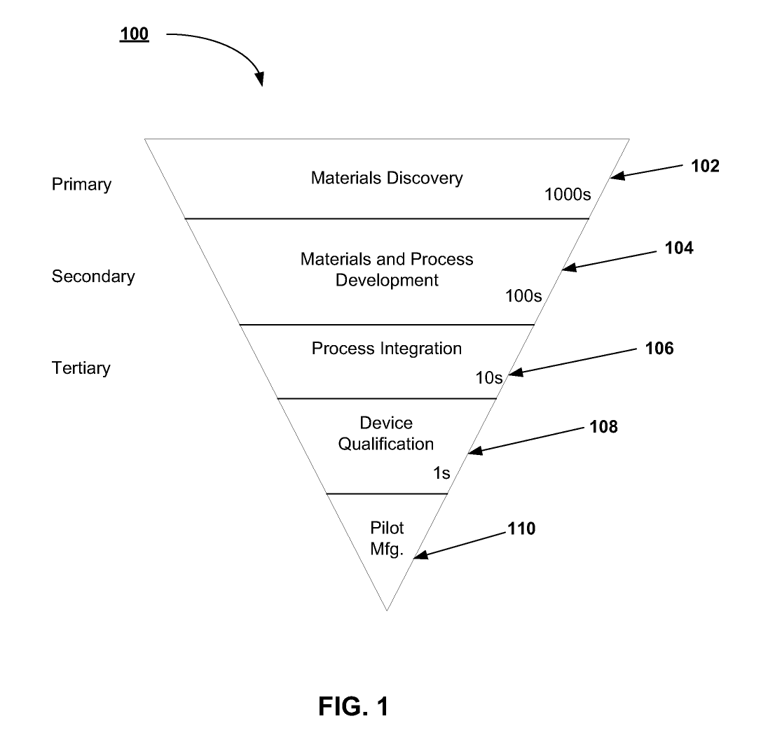

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of device fabrication processes by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed. A global optimum sequence order is therefore derived, and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate which are equivalent to the structures formed during actual production of the device. For example, such structures may include, but would not be limited to, gate dielectric layers, gate electrode layers, spacers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

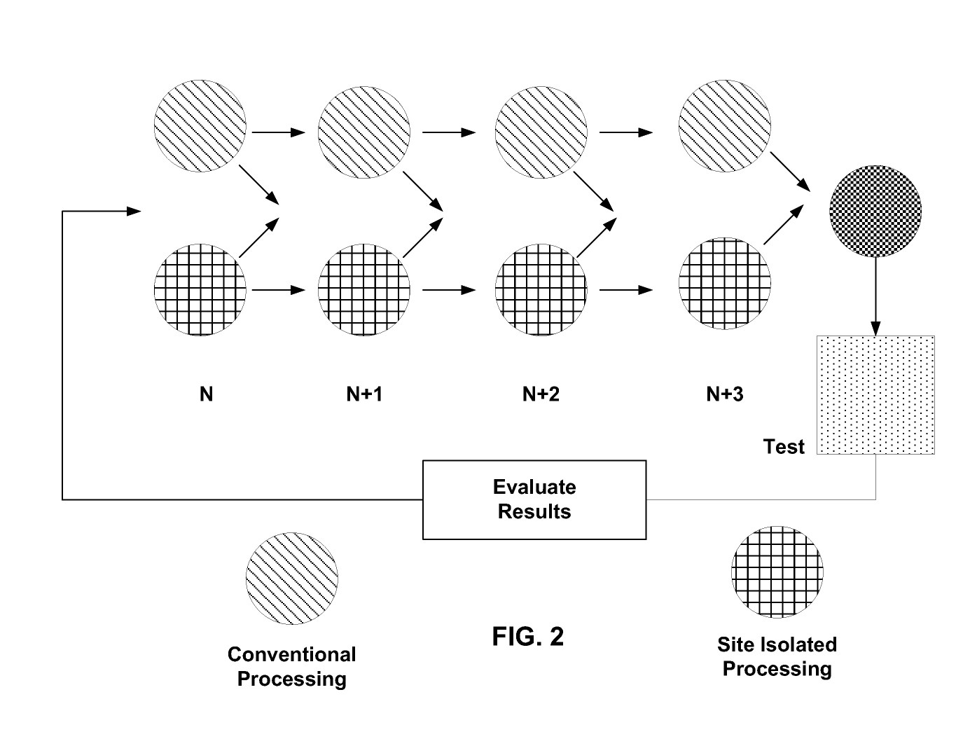

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Combinatorial processing can be used to produce and evaluate different materials, chemicals, processes, process and integration sequences, and techniques related to semiconductor fabrication. For example, combinatorial processing can be used to determine optimal processing parameters (e.g., power, time, reactant flow rates, temperature, etc.) of dry processing techniques such as dry etching (e.g., plasma etching, flux-based etching, reactive ion etching (RIE)) and dry deposition techniques (e.g., physical vapor deposition (PVD), chemical vapor deposition (CVD), atomic layer deposition (ALD), etc.). Combinatorial processing can be used to determine optimal processing parameters (e.g., time, concentration, temperature, stirring rate, etc.) of wet processing techniques such as wet etching, wet cleaning, rinsing, and wet deposition techniques (e.g., electroplating, electroless deposition, chemical bath deposition, etc.).

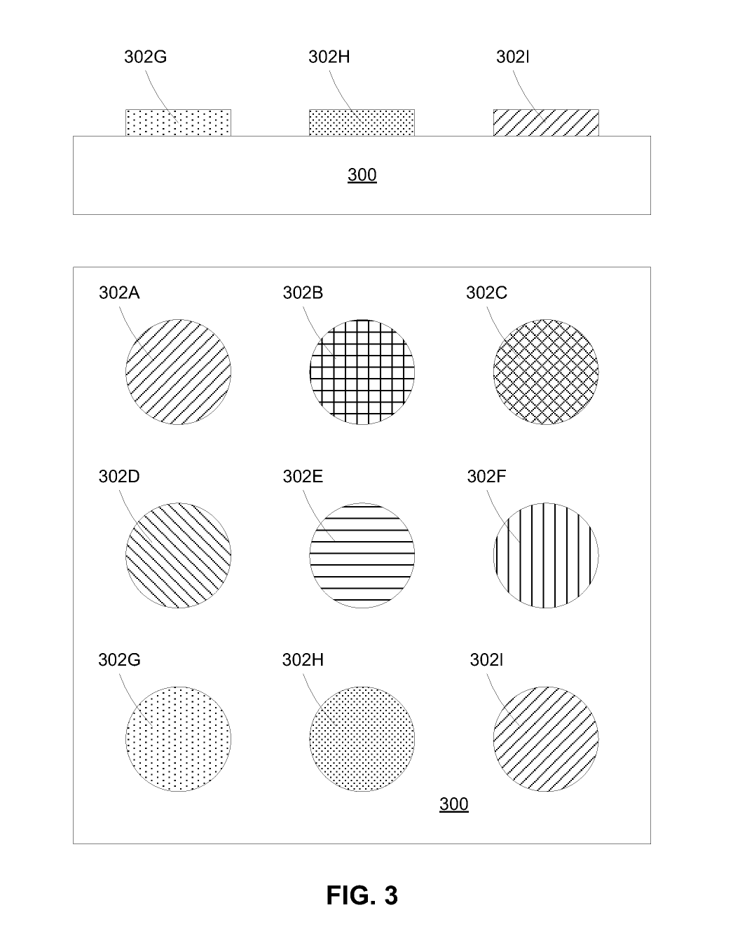

FIG. 3 illustrates a schematic diagram of a substrate that has been processed in a combinatorial manner. A substrate, 300, is shown with nine site isolated regions, 302A-302I, illustrated thereon. Although the substrate 300 is illustrated as being a generally square shape, those skilled in the art will understand that the substrate may be any useful shape such as round, rectangular, etc. The lower portion of FIG. 3 illustrates a top down view while the upper portion of FIG. 3 illustrates a cross-sectional view taken through the three site isolated regions, 302G-302I. The shading of the nine site isolated regions illustrates that the process parameters used to process these regions have been varied in a combinatorial manner. The substrate may then be processed through a next step that may be conventional or may also be a combinatorial step as discussed earlier with respect to FIG. 2.

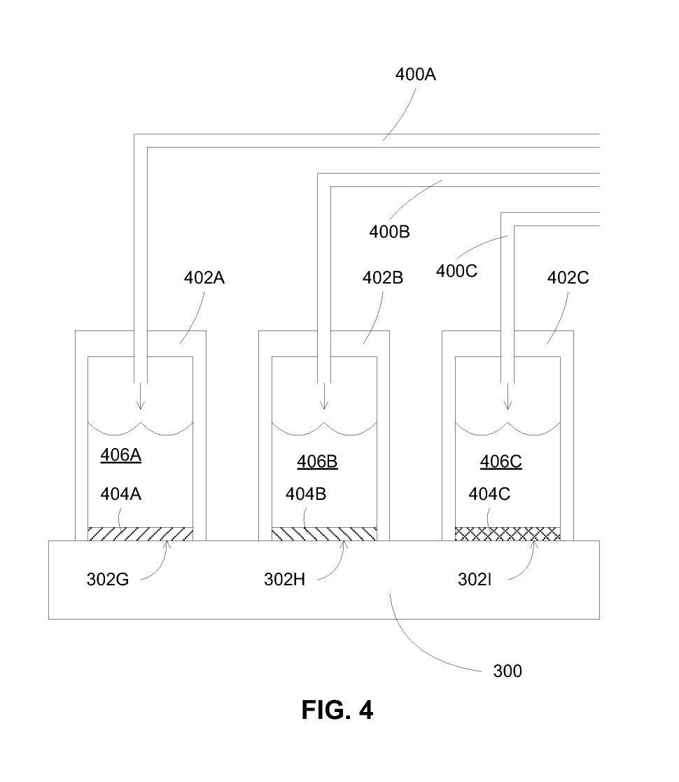

FIG. 4 illustrates a schematic diagram of a combinatorial wet processing system according to an embodiment described herein. A combinatorial wet system may be used to investigate materials deposited by solution-based techniques. An example of a combinatorial wet system is described in U.S. Pat. No. 7,544,574 cited earlier. Those skilled in the art will realize that this is only one possible configuration of a combinatorial wet system. FIG. 4 illustrates a cross-sectional view of substrate, 300, taken through the three site isolated regions, 302G-302I similar to the upper portion of FIG. 3. Solution dispensing nozzles, 400a-400c, supply different solution chemistries, 406A-406C, to chemical processing cells, 402A-402C. FIG. 4 illustrates the deposition of a layer, 404A-404C, on respective site isolated regions. Although FIG. 4 illustrates a deposition step, other solution-based processes such as cleaning, etching, surface treatment, surface functionalization, etc. may be investigated in a combinatorial manner. Advantageously, the solution-based treatment can be customized for each of the site isolated regions.

The manufacturing of advanced semiconductor devices can require substrate planarization. For example, photolithography process can pattern images at submicron line width, but requiring that the substrate be as flat as possible to enable optical focusing, since the depth of focus of the optical system is relatively small. One commonly used technique in semiconductor processing for planarizing the surface of a substrate is a polishing or chemical mechanical planarization (CMP) process, where the terms “planarization” and “polishing” are often used interchangeably.

The CMP process typically requires motion between the substrate surface and a polishing pad in the presence of a polishing slurry. Both mechanical planarization and chemical planarization processes are combined in a CMP process to produce a planar surface. For example, the relative motion of the substrate with respect to the polishing pad can produce mechanical abrasion, planarizing the surface. The slurry can react with the material on the substrate surface to produce chemical interaction, planarizing the surface.

The ability to conduct multiple experiments on a single substrate is generally desirable to evaluate new materials, chemicals and processes, especially in advanced semiconductor processing. It would be advantageous to perform CMP processing on multiple isolated regions on a substrate in a combinatorial manner.

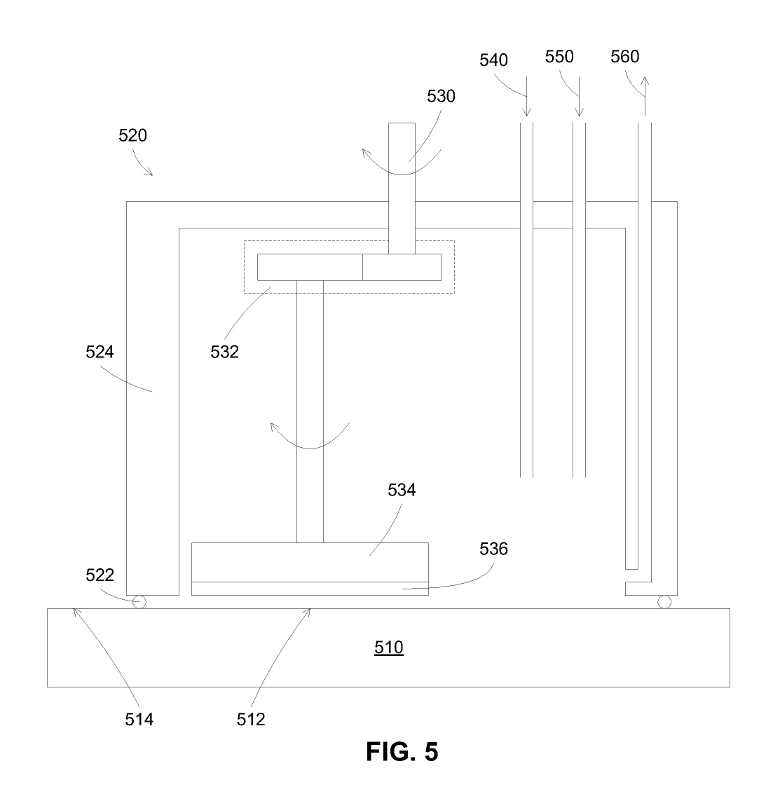

FIG. 5 illustrates an exemplary CMP reactor according to some embodiments of the present invention. A flow cell, e.g., a site isolated reactor 520 is disposed on a site isolated region 512 of a substrate 510. The chamber wall 524 of the reactor 520 can comprise a seal 522 to isolate the surface region 512 inside the reactor with the surface region 514 outside the reactor. An o-ring seal 522 is shown, but other forms of seal mechanism can be used, including non-contact seals, such as a gas bearing seal. A rotatable polishing head 534 is connected to a rotating axis 530 through a planetary gear 532. The polishing head 534 can comprise a polishing pad 536, configured to polish the surface 512 by a rotating mechanism while supplying a polishing fluid, e.g. slurry.

The planetary gear 532 allows the polishing head to rotate off center of the site isolated region 512, providing a uniform polishing surface. Alternatively, the polishing head can be coupled directly to the rotating axis 530, resulting in a center polishing action of the region 512.

The reactor 520 can further comprise a plurality of inlet and outlet conduits. For example, inlet conduit 550 can be coupled to a slurry distribution system to provide slurry to the reactor cell, which can assist the polishing head 534 in polishing the surface region 512. Inlet conduit 540 can be coupled to a chemical distribution system to provide chemicals, including deionized water, to the reactor cell. The chemicals can be used to clean or rinse the surface region 512 after CMP, including chemical rinsing and water rinsing. Outlet conduit 560 can be coupled to a vacuum exhaust to evacuate the materials within the reactor cell. The outlet conduit 560 is preferably disposed close to the substrate surface, and also within the reactor wall to avoid collision with the polishing head.

In operation, after the CMP reactor 520 is lowered on a substrate (or the substrate is raised to form a seal with the reactor), a CMP process is performed on the surface region 512 of the substrate within the interior volume of the reactor. A slurry is then delivered to the slurry conduit 550. The slurry flows onto the respective region 512 on the substrate 510, where it is restricted from flowing outward onto the surrounding surface portion of the substrate 510 by the seal 522. The polishing head is then lowered to the slurry surface, rotating to polish the surface region 512. The slurry can be supplied continuously, with excess materials being evacuated through the vacuum exhaust line 560.

After a predetermined amount of time, the rotation can stop, and the polishing head is raised from the surface region 512. Chemical rinsing, followed by water rinsing, can be performed, for example, through chemical supply conduit 540 and exhaust conduit 560. As such, the present invention allows for CMP processes to be performed on only particular portions of the substrate, without affecting any surface region outside the reactor 520.

Thus, in some embodiments, a substrate processing reactor is provided. The substrate processing reactor can comprise a reactor chamber comprising a chamber wall, wherein the chamber wall is disposed on a substrate surface to define a site isolated region on the substrate; a rotatable polishing head; a first conduit for distributing slurry to the site isolated region; a second conduit for distributing chemical to the site isolated region; and a third conduit for removing materials from the site isolated region. In some embodiments, the third conduit can be disposed within the chamber wall. The chamber wall contacts the substrate surface for forming a seal with the substrate surface. The chamber wall forms a non-contact seal with the substrate surface. In some embodiments, the reactor further comprises a planetary gear system coupled to the polishing head.

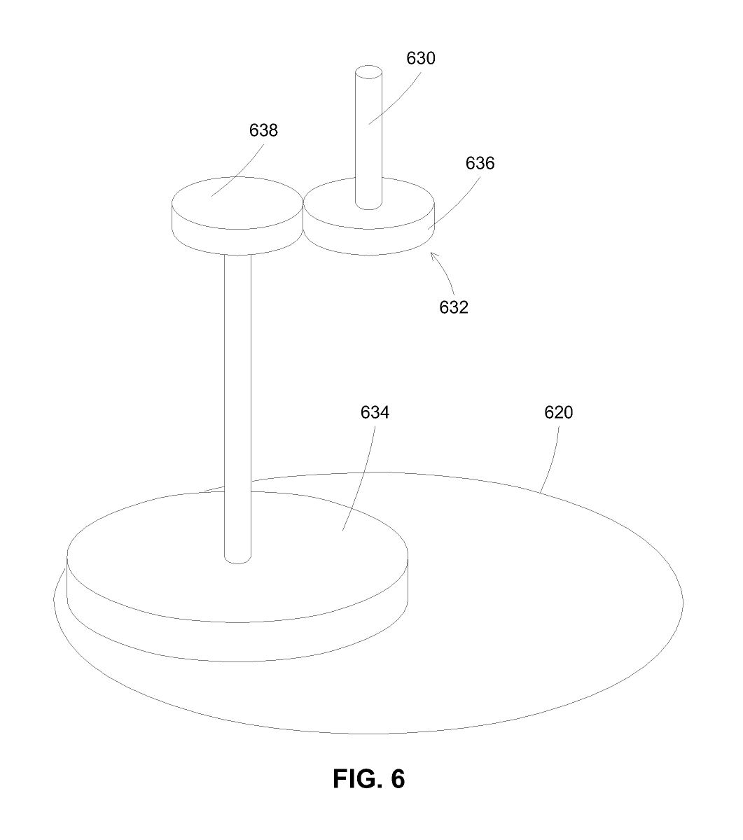

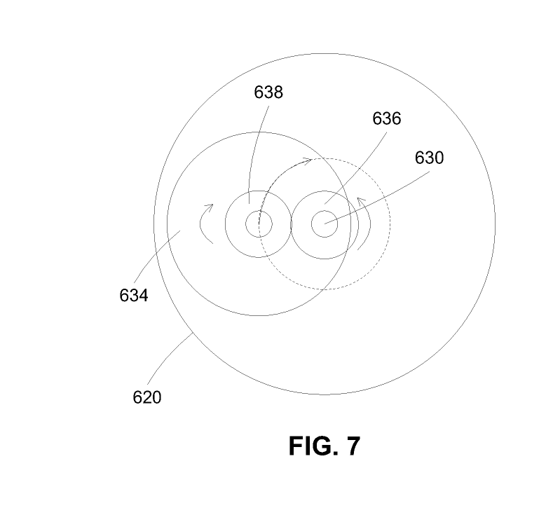

FIGS. 6-7 illustrate an exemplary planetary rotating polishing head according to some embodiments of the present invention. A central axis 630 can be coupled to a rotational mechanism, such as a motor, for turning gear 636. Gear 636 then rotates gear 638, which is coupled to polishing head 634. Gears 636 and 638 can form planetary gear system 632, converting a central rotation of axis 630 to off-center rotation of the polishing head 634 within the reactor wall 620.

In some embodiments, the present invention discloses CMP processes using site isolated reactors. With the reactors defining the site isolated regions, the substrate is stationary while the polishing head rotates. In addition, the chamber wall of the reactor can confine the isolated region, allowing cleaning or rinsing of the polishing area. The chamber wall can be cleaned during the cleaning of the site isolated region.

During CMP process, abrasive slurry can be flowed or dropped onto the site isolated region, which can cause splashes, forming residues scattered and stick to the chamber wall. The residues then can fall off to the polishing surface, creating scratched defects. Thus, in some embodiments, the chamber wall is periodically cleaned to wash off the slurry.

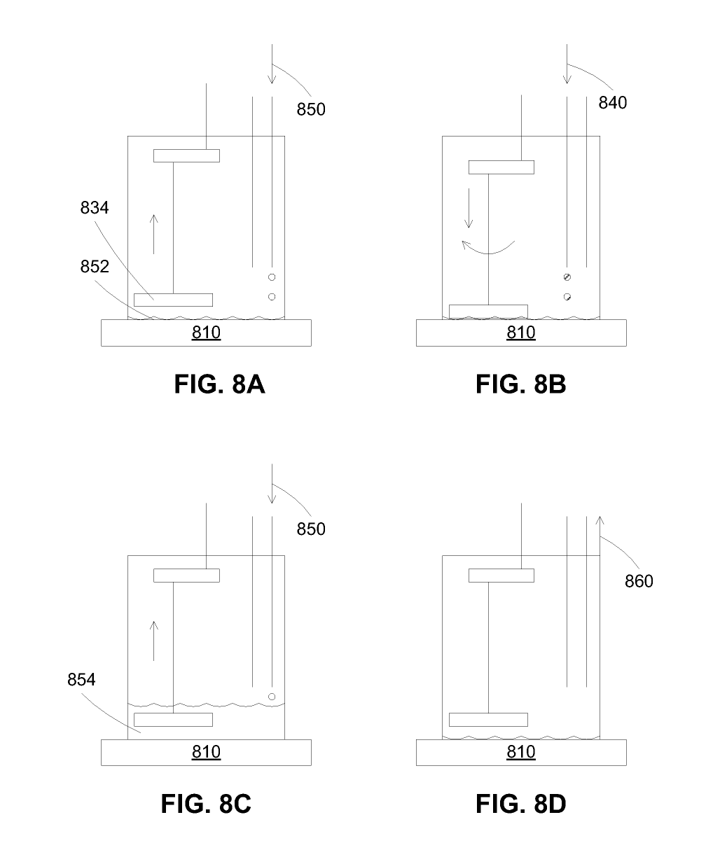

FIGS. 8A-8D illustrate an exemplary method for polishing a site isolated region according to some embodiments of the present invention. In FIG. 8A, the polishing head 834 is raised up from the substrate surface and chemical liquid 850 can be introduced to the reactor to wet 852 the surface region defined by the reactor wall. Alternatively, instead or in addition to chemical liquid 850, slurry 850 can be used. Also, the whole substrate can be wetted instead of individual reactor regions.

In FIG. 8B, the polishing head 834 is lowered to contact the surface, and rotated to polishing the surface. Slurry 840 can be introduced to the reactor region. The polishing is continued until a desired result is achieved, such as reaching a predetermined time or a predetermined thickness. In FIG. 8C, after complete processing, the polishing head is raised, and chemical or water 850 is introduced to the reactor chamber for cleaning and rinsing. The cleaning chemical also cleans the chamber wall in addition to any residues on the surface region. Since the polishing process is just completed, the slurry is not yet dried, and thus can be easily cleaned. In FIG. 8D, the chemical 850 is evacuated, for example, by a vacuum exhaust 860. The cleaning and draining can be repeated.

In some embodiments, the reactor can comprise additional components, such as an in-situ thickness measurement.

There can be residues at the interface of the chamber wall and the substrate surface, for example, caused by slurry pushing to the chamber wall by the polishing head. Substrate cleaning can be performed after CMP process for cleaning the residues.

In some embodiments, contact or non-contact reactors can be used. For example, an o-ring or sleeve can be used at the ends of the reactor wall for sealing the site isolated region. Alternatively, a gas barrier can be used to non-contact isolation of the reactor region. The gas barrier can be established by having a gas flowing from the chamber wall.

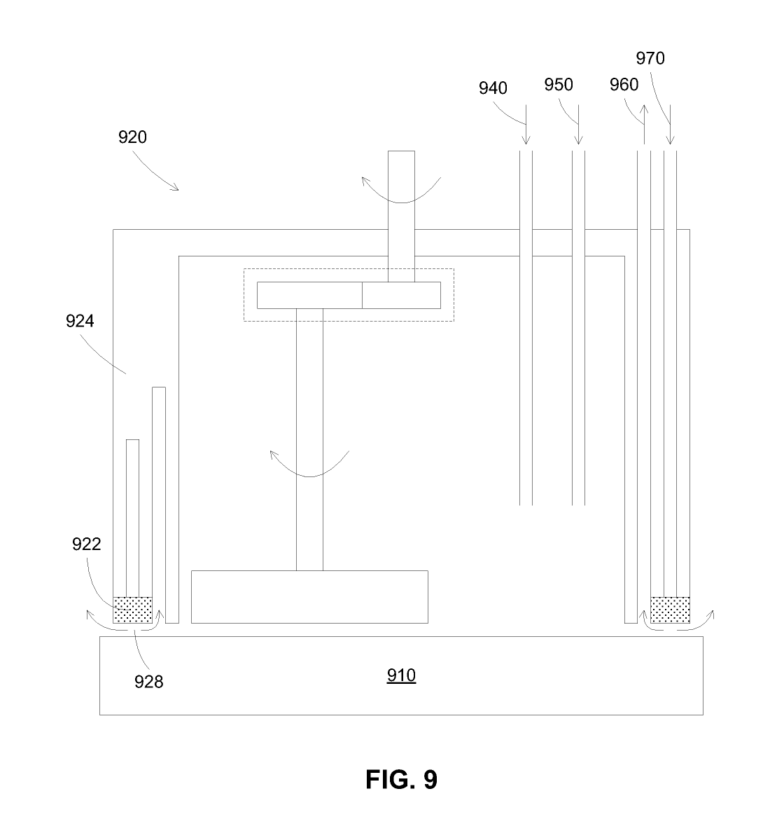

FIG. 9 illustrates a non-contact exemplary CMP reactor according to some embodiments of the present invention. A reactor 920 is disposed on a site isolated region of a substrate 910. The chamber wall 924 of the reactor 920 can comprise a non-contact seal 928 to isolate the surface region inside the reactor with the surface region outside the reactor. A gas bearing seal 928 is shown, comprising a gas flow to a porous element 922 to form a high pressure gas layer between the chamber wall and the substrate surface. Porous elements can be used to form non-contact reactor cell, as disclosed in co-pending patent application “TOUCHLESS SITE ISOLATION USING GAS BEARING”, application Ser. No. ______, attorney docket number IM0438_US, hereby incorporated by reference.

The reactor 920 can further comprise a plurality of inlet and outlet conduits. For example, inlet conduit 950 can be coupled to a slurry distribution system to provide slurry to the reactor cell. Inlet conduit 940 can be coupled to a chemical distribution system to provide chemicals to the reactor cell. Outlet conduit 960 can be coupled to a vacuum exhaust to evacuate the materials within the reactor cell. In addition, inlet 970 can be included to provide the gas flow to form the gas layer 928. The inlet 970 and the outlet 960 are preferably disposed within the chamber wall, forming a gas pressure region when coming to a close proximity with the substrate surface.

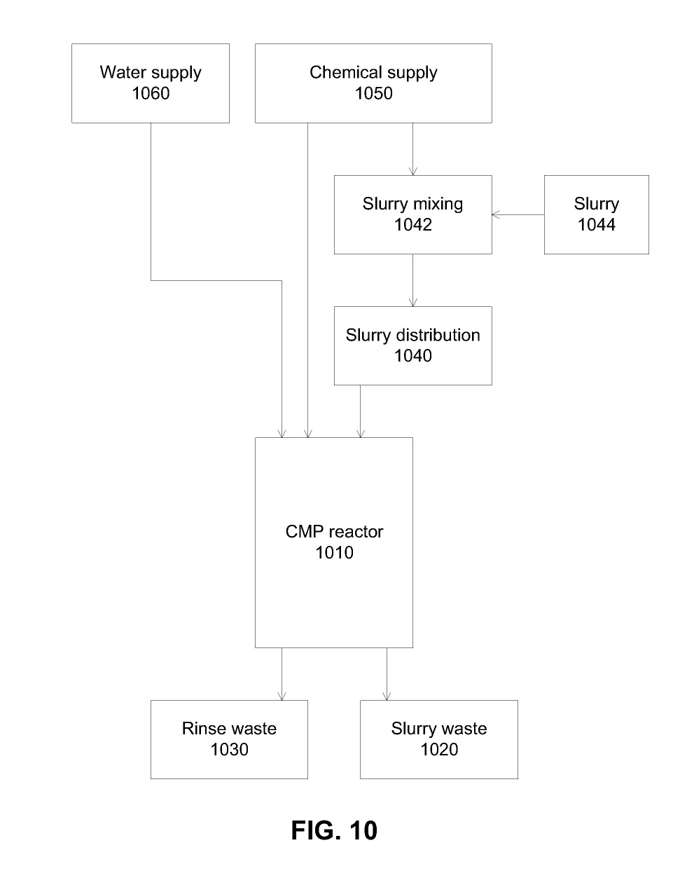

FIG. 10 illustrates an exemplary slurry and chemical distribution according to some embodiments of the present invention. Chemical supply 1050 and water supply 1060 can be coupled to the CMP reactor 1010 to provide chemicals and water to the reactor, for example, for processing, cleaning or rinsing the site isolated region or the reactor wall. Slurry supply 1044 can be coupled to a slurry mixing unit 1042, mixing slurry with chemical liquid coming from chemical supply 1050. After mixing, the slurry mixture can be provided to a slurry distribution 1040 to be distributed to the MCP reactor 1010. One or more drainages can be coupled to the CMP reactor 1010 for draining wastes from the reactor, such as cleaning or rinsing chemicals and slurry. The wastes can be separated to different containers, such as rinse waste 1030 and slurry waste 1020 for ease of disposal.

In some embodiments, the present invention discloses systems and methods for combinatorially polishing and evaluating multiple isolated regions on a substrate. Multiple CMP reactors can be used to process multiple site isolated regions on a single substrate. In addition, different reactor configurations can be used, such as wet cleaning, wet stripping, electroplating, etc., in addition to CMP processes.

In some embodiments, the present invention discloses a combinatorial system for CMP processing. An exemplary system comprises a substrate support for supporting a substrate; a plurality of reactors, wherein each reactor comprising a chamber wall, wherein the chamber wall is disposed on the substrate surface to define a site isolated region on the substrate; a rotatable polishing head; a first conduit for distributing slurry to the site isolated region; a second conduit for distributing chemical to the site isolated region; a third conduit for removing materials from the site isolated region. In some embodiments, the third conduit can be disposed within the chamber wall. The chamber wall can contact the substrate surface for forming a seal with the substrate surface. The chamber wall can form a non-contact seal with the substrate surface. The plurality of reactors process the site isolated regions in a combinatorial manner.

In some embodiments, the CMP reactor can further comprise a planetary gear system coupled to the polishing head, a slurry distribution assembly coupled to the first conduit, a water delivery assembly coupled to the second conduit, a chemical delivery assembly coupled to the second conduit, and a waste assembly coupled to the third conduit.

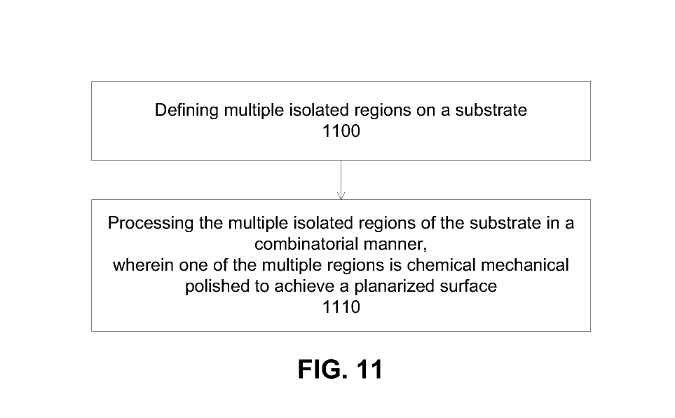

FIG. 11 illustrates an exemplary flowchart for polishing site isolated regions according to some embodiments of the present invention. Operation 1100 defines at least an isolated region on a substrate. Operation 1110 chemical mechanical polishes the at least an isolated region to achieve a planar surface. Multiple isolated regions can be defined on the substrate, with the multiple isolated regions chemical mechanical polished in a combinatorial manner.

In some embodiments, the method can further comprise wetting the isolated region; lowering a rotatable polishing head on the wetted isolated region; polishing an area of the isolated region while flowing slurry on another area of the isolated region; flowing a liquid to the isolated region for rinsing; and exhausting the liquid from the isolated region.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A reactor comprising
a reactor chamber comprising a chamber wall, wherein the chamber wall is disposed on a substrate surface to define a site isolated region on the substrate;
a rotatable polishing head;
a first conduit for distributing slurry to the site isolated region;
a second conduit for distributing chemical to the site isolated region;
a third conduit for removing materials from the site isolated region.

2. A reactor as in claim 1 further comprising
a planetary gear system coupled to the polishing head.

3. A reactor as in claim 1 wherein the third conduit is disposed within the chamber wall.

4. A reactor as in claim 1 wherein the chamber wall contacts the substrate surface for forming a seal with the substrate surface.

5. A reactor as in claim 1 wherein the chamber wall forms a non-contact seal with the substrate surface.

6. A combinatorial processing system comprising
a substrate support for supporting a substrate;
a plurality of reactors, wherein each reactor comprising a chamber wall, wherein the chamber wall is disposed on the substrate surface to define a site isolated region on the substrate;
a rotatable polishing head;
a first conduit for distributing slurry to the site isolated region;
a second conduit for distributing chemical to the site isolated region;
a third conduit for removing materials from the site isolated region.

7. A reactor as in claim 6 further comprising
a planetary gear system coupled to the polishing head.

8. A reactor as in claim 6 wherein the third conduit is disposed within the chamber wall.

9. A reactor as in claim 6 wherein the chamber wall contacts the substrate surface for forming a seal with the substrate surface.

10. A reactor as in claim 6 wherein the chamber wall forms a non-contact seal with the substrate surface.

11. A reactor as in claim 6 wherein the plurality of reactors process the site isolated regions in a combinatorial manner.

12. A reactor as in claim 6 further comprising
a slurry distribution assembly coupled to the first conduit.

13. A reactor as in claim 6 further comprising
a water delivery assembly coupled to the second conduit.

14. A reactor as in claim 6 further comprising
a chemical delivery assembly coupled to the second conduit.

15. A reactor as in claim 6 further comprising
a waste assembly coupled to the third conduit.

16. A method comprising
defining at least one isolated region on a substrate;
chemical mechanical polishing the at least one isolated region to achieve a planar surface.

17. A method as in claim 16 wherein multiple isolated regions are defined on the substrate, and wherein the multiple isolated regions are chemical mechanical polished in a combinatorial manner.

18. A method as in claim 16 further comprising
wetting the isolated region;
lowering a rotatable polishing head on the wetted isolated region.

19. A method as in claim 16 further comprising
polishing an area of the isolated region while flowing slurry on another area of the isolated region.

20. A method as in claim 16 further comprising
flowing a liquid to the isolated region for rinsing.
